(19) United States
(12) Patent Application Publication
(10) Pub. No.: US 2026/0165198 A1
(43) Pub. Date: Jun. 11, 2026

(54) ELECTRONIC DEVICE

(71) Applicant: Advanced Semiconductor Engineering, Inc., Kaohsiung (TW)

(72) Inventors: Fangwen LIN, Kaohsiung (TW); Peinung WU, Kaohsiung (TW); Chingyao HSU, Kaohsiung (TW); Jenchun CHEN, Kaohsiung (TW)

(73) Assignee: Advanced Semiconductor Engineering, Inc., Kaohsiung (TW)

(21) Appl. No.: 18/970,784

(22) Filed: Dec. 5, 2024

(51) Int. Cl. H01L 25/07; H01L 23/00; H01L 23/16; H01L 23/31

(52) U.S. Cl. CPC H10W 90/00; H10W 74/114; H10W 76/40; H10W 90/734; H10W 90/754; H10W 90/794

(57) ABSTRACT

The present disclosure provides an electronic device. The electronic device includes a first module, a second module, and an encapsulant. The first module includes a first power die with a first dimension. The second module is stacked over the first module and includes a component with a second dimension different from the first dimension. The encapsulant encapsulates the first module and the second module. The encapsulant defines a recess configured to accommodate an external device.

### BACKGROUND

### 1. Technical Field

The present disclosure relates to an electronic device.

### 2. Description of the Related Art

In a comparative method of packaging a power die (such as a power metal-oxide-semiconductor field-effect transistor (MOSFET) or an insulated gate bipolar transistor (IGBT)), two or more sets of MOSFET and IGBT are integrated. However, increasing the dimensions (e.g., thickness) can adversely impact the miniaturization of the electronic device.

### SUMMARY

In some arrangements, an electronic device includes a first module, a second module, and an encapsulant. The first module includes a first power die with a first dimension. The second module is stacked over the first module and includes a component with a second dimension different from the first dimension. The encapsulant defines a recess configured to accommodate an external device

In some arrangements, an electronic device includes a first carrier, a first die with a first dimension, and a second die with a second dimension less than the first dimension. The second die is at an elevation higher than an elevation of the first die with respect to the first carrier. The first die is laterally closer to a side of the first carrier than the second die is.

In some arrangements, an electronic device includes a first package structure, a first encapsulant, and a second package structure. The first package structure includes a carrier and a first encapsulant defining a plurality of recesses over the carrier. The plurality of recesses are configured to accommodate additional package structures

### BRI EF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a top view of an electronic device in accordance with some arrangements of the present disclosure.

FIG. 1B illustrates a cross-sectional view along line A-A′ of the electronic device as shown in FIG. 1A in accordance with some arrangements of the present disclosure.

FIG. 1C illustrates a cross-sectional view of an electronic device in accordance with some arrangements of the present disclosure.

FIG. 2A illustrates a top view of an electronic device in accordance with some arrangements of the present disclosure.

FIG. 2B illustrates a cross-sectional view of an electronic device in accordance with some arrangements of the present disclosure.

FIG. 3 illustrates a cross-sectional view of an electronic device in accordance with some arrangements of the present disclosure.

FIG. 4 illustrates a cross-sectional view of an electronic device in accordance with some arrangements of the present disclosure.

FIG. 5A, FIG. 5B, FIG. 5C, and FIG. 5D illustrate one or more stages of an example of a method for manufacturing an electronic device according to some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

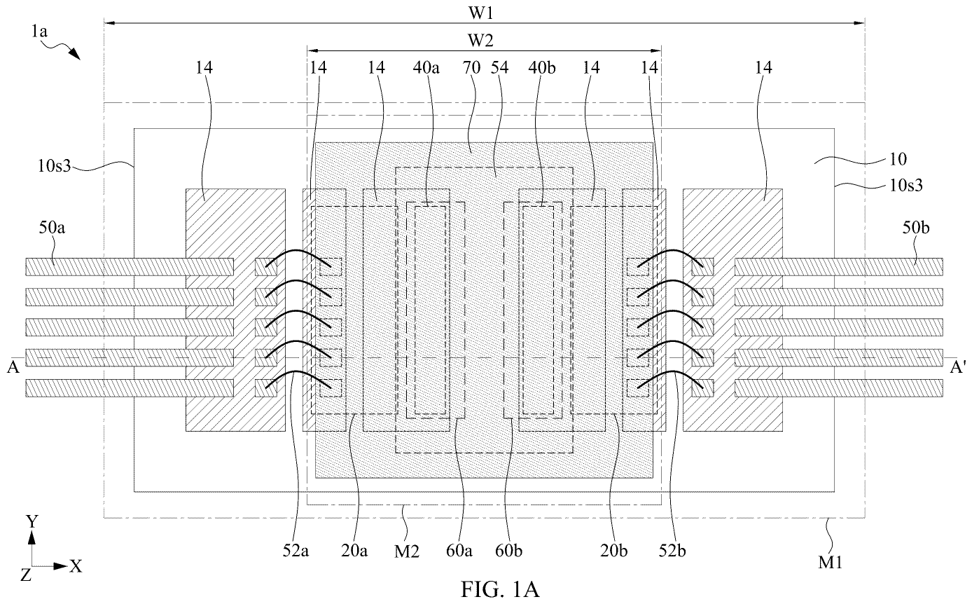

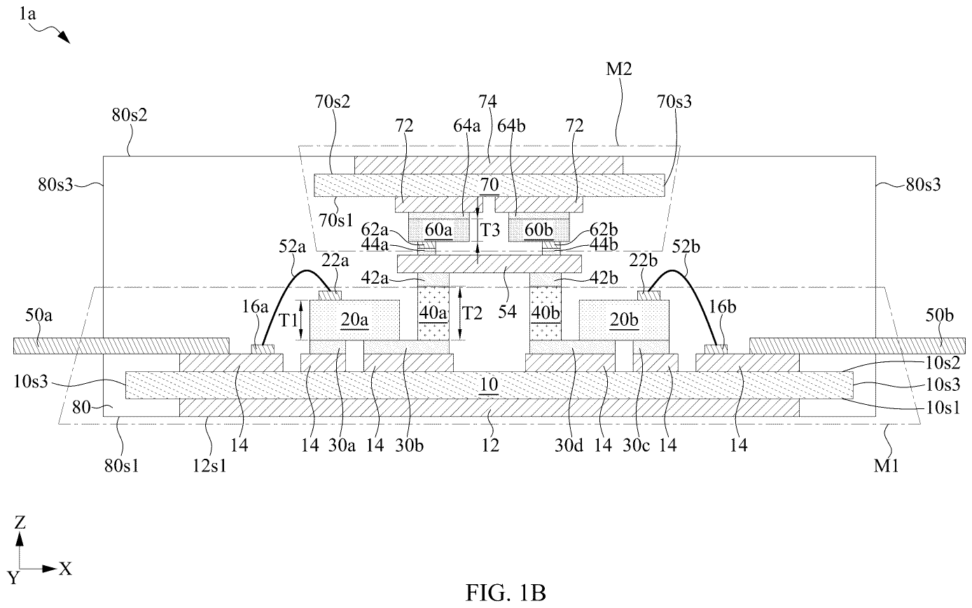

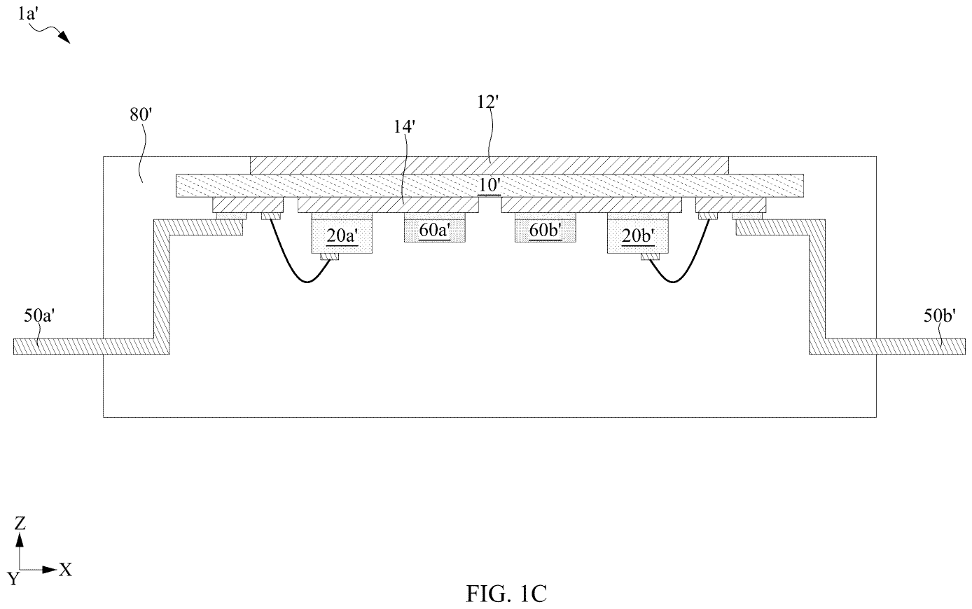

FIG. 1A illustrates a top view of an electronic device 1a in accordance with some arrangements of the present disclosure. FIG. 1B illustrates a cross-sectional view along line A-A′ of the electronic device 1a as shown in FIG. 1A in accordance with some arrangements of the present disclosure. It should be noted that some features are omitted from FIG. 1A for brevity.

Referring to FIG. 1A, the electronic device 1a may include a carrier 10, an electronic component 20a, electronic component 20b, spacer 40a, spacer 40b, terminals 50a, terminals 50b, electronic component 60a, electronic component 60b, and carrier 70. The carrier 10 may be configured to support the electronic components 20a and 20b, and spacers 40a and 40. The terminals 50a and terminals 50b may be configured to electrically connect the carrier 10 and an external device(s). The electronic components 60a and 60b may be disposed over the spacers 40a and 40b, respectively. The carrier 70 may be disposed over the carrier 10 and cover the electronic components 60a and 60b.

Referring to FIG. 1B, in some arrangements, the carrier 10 may include a direct bonded copper (DBC) substrate obtained by sintering and bonding conductive plates on both sides of the ceramic base using heat and pressure. In some arrangements, the carrier 10 may include a ceramic base (or other suitable materials) and a circuit pattern formed therein. The carrier 10 may have the advantage of excellent heat dissipation and heat conduction characteristics. The carrier 10 may have a surface 10s1 (or a lower surface) and a surface 10s2 (or an upper surface) opposite to the surface 10s1. The carrier 10 may have surfaces 10s3 (or lateral surfaces or sides) extending between the surface 10s1 and surface 10s2. The carrier 10 may include a conductive plate 12 and a conductive plate 14.

The conductive plate 12 may be disposed on or under the surface 10s1 of the carrier 10. The conductive plate 12 may include a patterned trace configured to electrically connect an external device (not shown). The conductive plate 14 may be disposed on or over the surface 10s2 of the carrier 10. The conductive plate 14 may include a patterned trace configured to electrically connect elements or devices. The conductive plate 12 and conductive plate 14 may include copper, aluminum, gold, silver, titanium, or other suitable materials.

The electronic components 20a and 20b may be disposed on or over the surface 10s2 of the carrier 10. In some arrangements, each the electronic components 20a and 20b may include a die (e.g., a power die) or a chip including a semiconductor substrate, one or more integrated circuit devices and/or one or more overlying interconnection structures therein. The integrated circuit devices may include active devices such as transistors and diodes. The integrated circuit devices may include passive devices such resistors, capacitors, inductors, or a combination thereof. In some arrangements, each the electronic components 20a and 20b may include a power metal-oxide-semiconductor field-effect transistor (MOSFET) device, an insulated gate bipolar transistor (IGBT) device, and/or a junction gate field-effect transistor (JFET) device.

The electronic component 20a may be electrically connected to the conductive plate 14 through electrical connectors 30a and 30b. The electronic component 20b may be electrically connected to the conductive plate 14 through electrical connectors 30c and 30d.

In some arrangements, the electronic component 20a may include three terminals (e.g., gate, source and drain), which may be electrically connected to other devices by electrical connectors 22a, 30a, and 30b. The electrical connectors 22a, 30a, and 30b may include, for example, a conductive pad, a solder material, or other suitable elements. The reflowable material may include a reflowable material. The reflowable material may include alloys of gold and tin solder or alloys of silver and tin solder, or other suitable materials. In some arrangements, the electrical connector 22a may be disposed on an upper surface of the electronic component 20a, and the electrical connectors 30a and 30b may be disposed under a lower surface of the electronic component 20a.

In some arrangements, the electronic component 20b may include three terminals (e.g., gate, source and drain), which may be electrically connected to other devices by electrical connectors 22b, 30c, and 30d. The 22b, 30c, and 30d may include, for example, a conductive pad, a solder material, or other suitable elements. The reflowable material may include a reflowable material. In some arrangements, the electrical connector 22b may be disposed on an upper surface of the electronic component 20b, and the electrical connectors 30c and 30d may be disposed under a lower surface of the electronic component 20b.

In some arrangements, the spacers 40a and 40b may be disposed on the surface 10s2 of the carrier 10. The spacers 40a and 40b may be disposed on the conductive plate 14. In some arrangements, the spacer 40a and electronic component 20a may be arranged side by side. For example, the spacer 40a may laterally overlap the electronic component 20a or overlap the electronic component 20a along the X direction. In some arrangements, the spacer 40a may be electrically connected to the electronic component 20a through the electrical connector 30b and/or carrier 10. In some arrangements, the spacer 40b and electronic component 20b may be arranged side by side. For example, the spacer 40b may laterally overlap the electronic component 20b or overlap the electronic component 20b along the X direction. In some arrangements, the spacer 40b may be electrically connected to the electronic component 20b through the electrical connector 30d and/or carrier 10.

In some arrangements, the spacers 40a and 40b may be configured to adjust the elevation (or level) of the electronic components 60a and 60b or adjust the overall thickness of the electronic device 1a. In some arrangements, the spacers 40a and 40b may include copper, aluminum, gold, silver, titanium, or other suitable materials. In some arrangements, the spacers 40a and 40b are disposed on a central region, and the electronic components 20a and 20b are disposed at a peripheral region of the electronic device 1a. For example, the electronic component 20a is closer to the surface 10s3 of the carrier 10 than the spacer 40a is along the X direction. In some arrangements, the spacer 40a (or spacer 40b) may be disposed between the electronic components 20a and 20b.

The electronic component 20a (or electronic component 20b) may have a thickness T1 along the Z direction. The spacer 40a (or spacer 40b) may have a thickness T2 along the Z direction. In some arrangements, the thickness T2 may be greater than the thickness T1.

The terminals 50a and terminals 50b may be disposed on or over the surface 10s2 of the carrier 10. In some arrangements, the terminals 50a may be electrically connected to the electronic component 20a by a conductive wire 52a and a pad 16a over the conductive plate 14. In some arrangements, the terminals 50b may be electrically connected to the electronic component 20b by a conductive wire 52b and a pad 16b over the conductive plate 14. In some arrangements, each the terminals 50a and terminals 50b may be a part of a leadframe or other suitable conductive features. In some arrangements, the terminals 50a and terminals 50b may include leads, or other suitable elements. In some arrangements, the terminals 50a and terminals 50b may provide an external connection between the electronic device 1a and other components (not shown).

In some arrangements, the conductive wires 52a and 52b (or conductive elements or bendable conductive elements) may include a bonding wire which is bendable. The conductive wires 52a and 52b may include copper, nickel, gold, silver, or other suitable materials.

In some arrangements, the electronic device 1a further includes a conductive feature 54. In some arrangements, the conductive feature 54 may be disposed on or over the surface 10s2 of the carrier 10. In some arrangements, the conductive feature 54 may cover the spacers 40a and 40b. In some arrangements, the conductive feature 54 may be disposed between the electronic component 60a and the spacer 40a. In some arrangements, the elevation of the conductive feature 54 may be higher than that of the conductive wire 52a. In some arrangements, the conductive feature 54 may be electrically connected to the spacer 40a through an electrical connector 42a. In some arrangements, the conductive feature 54 may be electrically connected to the spacer 40b through an electrical connector 42b. The electrical connectors 42a and 42b may include a reflowable material, such as a solder material, which may include alloys of gold and tin solder or alloys of silver and tin solder, or other suitable materials. The electrical connectors 42a and 42b may include may include a conductive paste which is cured after heated. The conductive feature 54 may be configured to support the electronic components 60a and 60b. In some arrangements, the electronic component 20a is closer to the surface 10s3 of the carrier 10 than the conductive feature 54 is in a top view. The conductive feature 54 may include copper, aluminum, gold, silver, titanium, or other suitable materials.

In some arrangements, the conductive feature 54 (or a patterned conductive feature) may include a patterned trace or a patterned circuit disposed within a dielectric structure. The patterned trace or patterned circuit may be configured to provide a first electrical path between the electronic components 60a and 60b. The patterned trace or patterned circuit may be configured to provide a second electrical path between the electronic components 20a and 20b. The patterned trace or patterned circuit may be configured to provide a third electrical path between the electronic components 20a and 60b. The patterned trace or patterned circuit may be configured to provide a fourth electrical path between the electronic components 20b and 60a. Further, the conductive feature 54 may be configured to provide more distinct electrical paths. The first, second, third, and fourth electrical paths are different from each other, and can be turned on or switched independently without shorting.

In some arrangements, the electronic components 60a and 60b are disposed on or over the surface 10s2 of the carrier 10. In some arrangements, the electronic components 60a and 60b may be arranged side by side. In some arrangements, the electronic components 60a and 60b are disposed on or over the conductive feature 54. In some arrangements, the electronic component 60a may be disposed on or over the spacer 40a. The electronic component 60a may vertically overlap the spacer 40a or overlap the spacer 40a along the Z direction. In some arrangements, the electronic component 60b may be disposed on or over the spacer 40b. The electronic component 60b may vertically overlap the spacer 40b or overlap the spacer 40b along the Z direction. In some arrangements, the electronic component 60a may be electrically connected to the electronic component 20a by the spacer 40a.

In some arrangements, each the electronic components 60a and 60b may include a power metal-oxide-semiconductor field-effect transistor device, an insulated gate bipolar transistor device, and/or a junction gate field-effect transistor device. In some arrangements, the electronic components 20a and 20b may include transistors, and electronic components 60a and 60b may include IGBTs. In some arrangements, the electronic components 20a, 20b, 60a, and 60b may be configured to function as a converter, converting an input alternating current (AC) power to direct current (DC) power.

In some arrangements, the electronic component 60a may include two terminals (e.g., cathode and anode). For example, the electronic component 60a may include an electrical connector 62a and an electrical connector 64a on opposite sides of the electronic component 60a. The electrical connector 62a may be electrically connected to the conductive feature 54 by an electrical connector 44a. The electronic component 60b may include an electrical connector 62b and an electrical connector 64b on opposite sides of the electronic component 60b. The electrical connector 62b may be electrically connected to the conductive feature 54 by an electrical connector 44b. In some arrangements, the electronic component 60a may be electrically connected to the spacer 40a. In some arrangements, the electronic component 60b may be electrically connected to the spacer 40b. The electrical connectors 62a, 62b, 64a, and 64b may include copper, aluminum, gold, silver, titanium, or other suitable materials. The electrical connectors 62a, 62b, 64a, and 64b may include a reflowable material, such as a solder material, which may include alloys of gold and tin solder or alloys of silver and tin solder, or other suitable materials.

In some arrangements, the electronic component 60a may have a dimension (e.g., volume, surface area, width, length, or the like) less than that of the electronic component 20a. In some arrangements, the electronic components 60a and 60b may be disposed at a central region of the electronic device 1a (or the carrier 10). For example, the electronic component 20a is closer to the surface 10s3 of the carrier 10 than the electronic component 60a is in a top view. The electronic component 60a (or electronic component 60b) may have a thickness T3 along the Z direction. In some arrangements, the thickness T3 may be less than the thickness T1. In some arrangements, the electronic component 60a may be at an elevation (or level), with respect to the surface 10s2 of the carrier 10, higher than that of the electronic component 20a. In some arrangements, the electronic component 60a may be free from laterally overlapping the electronic component 20a.

In some arrangements, the carrier 70 may be disposed on or over the surface 10s2 of the carrier 10. In some arrangements, the carrier 70 may cover the electronic components 60a and 60b. In some arrangements, the carrier 70 may cover the conductive feature 54. In some arrangements, the carrier 70 may cover the spacers 40a and 40b. The carrier 70 may include a ceramic base (or other suitable materials) and a circuit pattern formed therein. In some arrangements, the carrier 70 may include a direct bonded copper (DBC) substrate obtained by sintering and bonding conductive plates on both sides of the ceramic base using heat and pressure. The carrier 70 may have the advantage of excellent heat dissipation and heat conduction characteristics. The carrier 70 may have a surface 70s1 (or a lower surface) and a surface 70s2 (or an upper surface) opposite to the surface 70s1. The carrier 70 may have surfaces 70s3 (or lateral surfaces or sides) extending between the surface 70s1 and surface 70s2. In some arrangements, the carrier 10 and carrier 70 have different dimensions (e.g., surface area). In some arrangements, the dimension of the carrier 70 may be less than that of the carrier 10. In some arrangements, the carrier 70 may vertically overlap the electronic components 20a and 20b.

The conductive plate 72 may be disposed on or under the surface 70s1 of the carrier 70. The conductive plate 72 may include a patterned trace electrically connected to the electronic component 60a (or electronic component 60b). The conductive plate 74 may be disposed on or over the surface 70s2 of the carrier 70. The conductive plate 74 may include a patterned trace configured to provide an external connection between the electronic device 1a and other devices (not shown). In some arrangements, the carrier 10 and carrier 70 have different dimensions (e.g., surface area).

In some arrangements, the electronic devices 1a may include a module M1 and a module M2 stacked over the module M1. In some arrangements, the modules M1 and M2 may be configured to function as a converter, converting an input alternating current power to direct current power.

In some arrangements, the module M1 may include the carrier 10, the electronic components 20a and 20b. In some arrangements, the module M1 may further include the spacers 40a and 40b. In some arrangements, the module M1 may further include the conductive feature 54. In some arrangements, the module M2 may include electronic components 60a and 60b and the carrier 70. In some arrangements, the dimension (e.g., surface area, width, length, and the like) of the module M1 may be greater than the module M2. For example, as shown in FIG. 1, a width W1 of the module M1 may be greater than a width W2 of the module M2 along the X direction. In some arrangements, the module M2 may be connected to the module M1 by the spacer 40a and/or spacer 40b. The conductive feature 54 may support the module M2.

In some arrangements, the electronic device 1a may include an encapsulant 80. In some arrangements, the encapsulant 80 may be disposed on or over the surface 10s2 of the carrier 10. In some arrangements, the encapsulant 80 may cover the surface 10s3 of the carrier 10. In some arrangements, the encapsulant 80 may encapsulate the module M1 and module M2. In some arrangements, the encapsulant 80 may encapsulate the electronic components 20a and 20b. In some arrangements, the encapsulant 80 may encapsulate a portion of the terminals 50a and terminals 50b. In some arrangements, the encapsulant 80 may encapsulate the spacers 40a and 40b. In some arrangements, the encapsulant 80 may encapsulate the electronic components 60a and 60b. In some arrangements, the encapsulant 80 may encapsulate the carrier 70.

The encapsulant 80 may have a surface 80s1 (or a lower surface), a surface 80s2 (or an upper surface) opposite to the surface 80s1, and a surface 80s3 (or a lateral surface or side) extending between the surface 80s1 and surface 80s2. The surface 80s1 may be substantially aligned with a lower surface of the conductive plate 12. The surface 80s2 may be substantially aligned with an upper surface of the conductive plate 74. The terminals 50a may be protruded from the surface 80s3. The terminals 50b may be protruded from the surface 80s3. The electronic component 20a is closer to the surface 80s3 than the electronic component 60a is. The encapsulant 80 may include a novolac-based resin, an epoxy-based resin, a silicone-based resin, or another suitable material. The encapsulant 80 may be applied using any of a number of molding techniques, such as compression molding, injection molding, or transfer molding.

In this arrangement, the smaller dimension component (e.g., the electronic component 60a) is positioned at the central region of the electronic device 1a, while the larger dimension component (e.g., the electronic component 20a) is placed at the peripheral region. Additionally, the smaller component is situated at a different elevation (or level) than the larger component. This configuration allows for a higher component density in the electronic device 1a compared to a comparative example.

FIG. 1C illustrates a cross-sectional view of an electronic device 1a′ in accordance with some arrangements of the present disclosure. The electronic device 1a′ includes a carrier 10′, electronic components 20a′, 20b′, 60a′, and 60b′, terminals 50a′ and 50b′, and an encapsulant 80′. The carrier 10′ may include conductive plates 12′ and 14′. The electronic components 20a′, 20b′, 60a′, and 60b′ may be disposed on or under the conductive plate 14′. The terminals 50a′ and 50b′ may be protruded from the lateral surface of the encapsulant 80′. The encapsulant 80′ may encapsulate the electronic components 20a′, 20b′, 60a′, and 60b′. In this arrangement, the electronic device 1a′ has a single module. No components (e.g., electronic components) are disposed within the space between the terminals 50a′ and 50b′ and under the electronic component 20a′, 20b′, 60a′, and 60b′. Therefore, the component density of the electronic device 1a′ is less than that of the electronic device 1a. Further, the electronic components 20a′, 20b′, 60a′, and 60b′ are arranged side by side, increasing the dimension along a plane defined by the X direction and the Y direction.

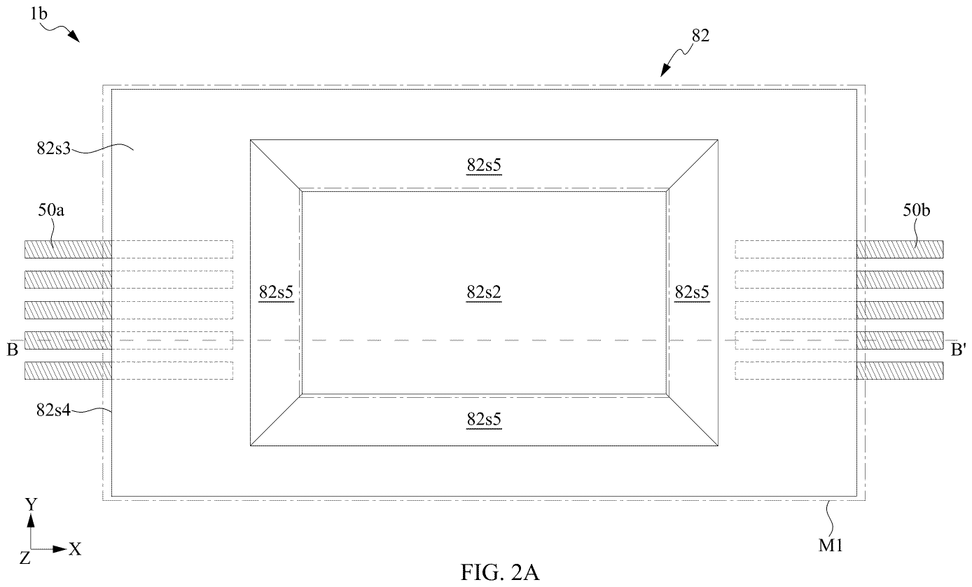

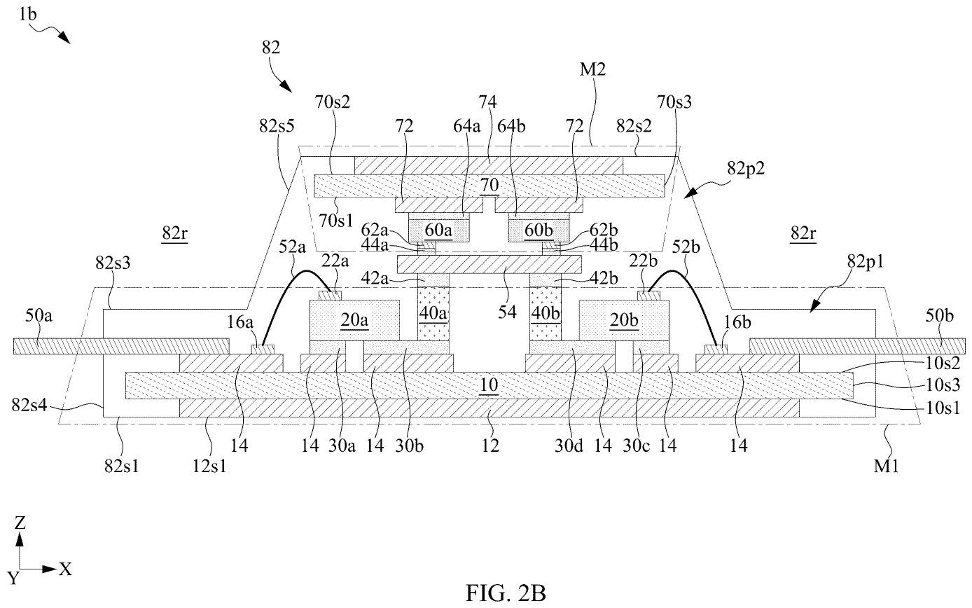

FIG. 2A illustrates a top view of an electronic device 1b, and FIG. 2B illustrates a cross-sectional view of the electronic device 1b in accordance with some arrangements of the present disclosure. The electronic device 1b is similar to the electronic device 1a except for the differences described as follows.

In some arrangements, the electronic device 1b may include an encapsulant 82. The encapsulant 82 may be formed by a selective molding technique, which may adjust the profile of the encapsulant 82. In some arrangements, the encapsulant 82 may have a portion 82p1 and a portion 82p2. In some arrangements, the portion 82p1 (or a base portion) may have a substantially uniform thickness along the Z direction. A uniform thickness as used in the disclosure, means that the thickness of a component is approximately the same within a certain tolerance. For example, a uniform thickness may mean that the thickness is the same within a certain percentage (e.g., 10%, 5% or less) of the average thickness of the material. In some arrangements, the encapsulant 82 may encapsulate the carrier 10. The encapsulant 82 may encapsulate the terminals 50a and terminals 50b. In some arrangements, the encapsulant 82 may encapsulate the at least a portion of the module M1.

The portion 82p2 (or a tapered portion) may be disposed on or over the portion 82p1. In some arrangements, the encapsulant 82 may be tapered toward a direction away from the portion 82p1. In some arrangements, the encapsulant 82 may encapsulate at least a portion of the module M1. In some arrangements, the encapsulant 82 may encapsulate the module M2. In some arrangements, the portion 82p2 may encapsulate the electronic components 60a and 60b. In some arrangements, the portion 82p2 may encapsulate the carrier 70.

In some arrangements, the encapsulant 82 may have a surface 82s1 (or a lower surface), a surface 82s2 (or an upper surface), and a surface 82s3 (or an upper surface) which is at an elevation between those of the surface 82s1 and surface 82s2. The encapsulant 82 may have a surface 82s4 (or a lateral surface) extending between the surface 82s1 and surface 82s3. In some arrangements, the encapsulant 82 may have a surface 82s5 (or a lateral surface) extending between the surface 82s2 and surface 82s3. The surface 82s4 and surface 82s5 may be referred to as the side of the encapsulant 82. In some arrangements, the surface 82s5 may be slanted with respect to the surface 82s3 (or surface 82s2). In some arrangements, the surface 82s5 may be slanted with respect to the surface 10s2 of the carrier 10.

In some arrangements, the encapsulant 82 may define a recess 82r. In some arrangements, the recess 82r may be located over the module M1. In some arrangements, the encapsulant 82 may be located over the carrier 10. The surface 82s3 and surface 82s4 may define the space of the recess 82r. The surface 82s3 may function as the bottom of the recess 82r, and the surface 82s4 may function as the sidewall of the recess 82r. In some arrangements, the recess 82r may be laterally overlap the module M2. In some arrangements, the recess 82r may be configured to accommodate one or more external devices, which may enhance the component density of the electronic device 1b.

In some arrangements, the encapsulant 82 may define recesses with different dimensions. For example, the encapsulant 82 may have an additional upper surface between the surfaces 82s1 and 82s2. The additional upper surface may be at an elevation different from that of the surface 82s3 so that the recess defined by the additional upper surface may have a dimension different from that of the recess 82r along the Z direction. Further, the additional upper surface may have a surface area different from that of the surface 82s3 so that the recess defined by the additional upper surface may have a dimension different from that of the recess 82r along a plane defined by the X direction and the Y direction.

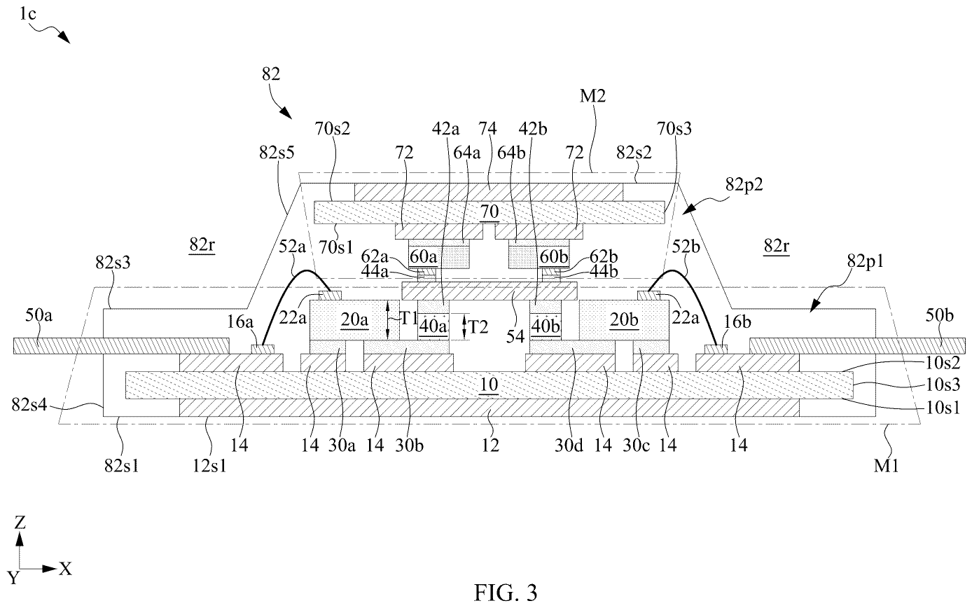

FIG. 3 illustrates a cross-sectional view of an electronic device 1c in accordance with some arrangements of the present disclosure. The electronic device 1c is similar to the electronic device 1b in FIG. 2B except for the differences described as follows.

In some arrangements, the thickness T2 of the spacer 40a may be less than the thickness T1 of the electronic component 20a. In some arrangements, the electrical connector 44 may laterally overlap the electronic component 20a. In this arrangement, the thickness of the overall structure can be reduced.

In some arrangements, the thickness of the spacer 40a is substantially the same as that of the spacer 40b. In other arrangements, the thickness of the spacer 40a is different from that of the spacer 40b. In this condition, the module M2 may be positioned at a slight angle relative to the module M1 without compromising the formation of the encapsulant 82. In this condition, a release film of a mold chase may be configured to compensate the thickness tolerance generated by the tilt of the module M2.

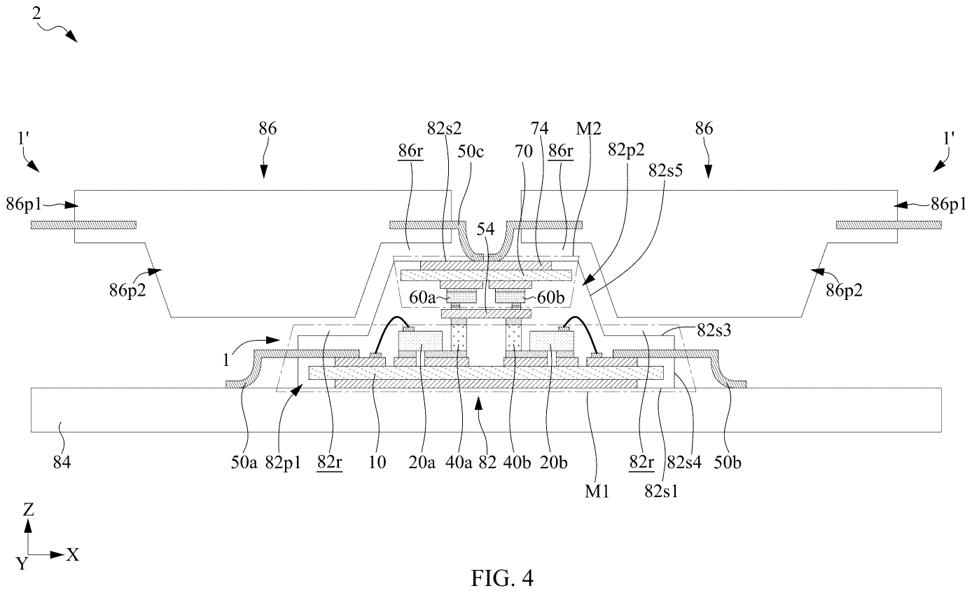

FIG. 4 illustrates a cross-sectional view of an electronic device 2 in accordance with some arrangements of the present disclosure. In some arrangements, the electronic device 2 may include a package structure 1 and one or more package structures 1′. In some arrangements, the package structure 1 may include a structure similar to or the same as that of the electronic device 1b or electronic device 1c. In some arrangements, the package structure 1′ may include a structure similar to or the same as that of the electronic device 1b or electronic device 1c. In some arrangements, the package structure 1′ may include an antenna device, an optical module, an interposer, or other devices.

In some arrangements, the electronic device 2 may include a circuit structure 84. The circuit structure 84 may be configured to support the package structure 1. The circuit structure 84 is formed of, for example, a printed circuit board, such as a paper-based copper foil laminate, a composite copper foil laminate, or a polymer-impregnated glass-fiber-based copper foil laminate. The circuit structure 84 may include a redistribution layer (RDL) or traces, for electrical connection between components. The package structure 1 may be electrically connected to the circuit structure 84 by the terminals 50a and/or terminals 50b.

In some arrangements, the package structure 1′ may be disposed on or over the package structure 1. In some arrangements, the package structure 1′ may encroach or occupy the recess 82r defined by the encapsulant 82. In some arrangements, the package structure 1′ may laterally overlap the module M2 of the package structure 1. In some arrangements, the package structure 1′ may have an encapsulant or housing 86. The encapsulant or housing 86 may define a recess 86r. In some arrangements, the encapsulant or housing 86 may have a profile the same as or similar to that of the encapsulant 82. In some arrangements, the profile of the encapsulant or housing 86 may fit or at least partially fit the recess 82r. The encapsulant or housing 86 may include a portion 86p1 (or a base portion) and a portion 86p2 (or a tapered portion). The portion 86p2 may be tapered toward the portion 82p1 of the encapsulant 82. In some arrangements, the portion 86p2 may be disposed within the recess 86r.

The package structure 1′ may include terminals 50c. The terminals 50c may be protruded from the portion 86p1 of the encapsulant or housing 86. In some arrangements, the package structure 1′ may be electrically connected to the package structure 1 by the terminals 50c. In some arrangements, the package structures 1′ may be electrically connected to each other by the terminals 50c and the conductive plate 74. The terminals 50c may function as a supporter, which is electrically conductive, to support the package structure 1′.

In some arrangements, the package structure 1 can accommodate one or more external devices by utilizing the recess 82r, allowing for stacking or integration. This can result in a reduction in the overall size of the electronic device 2.

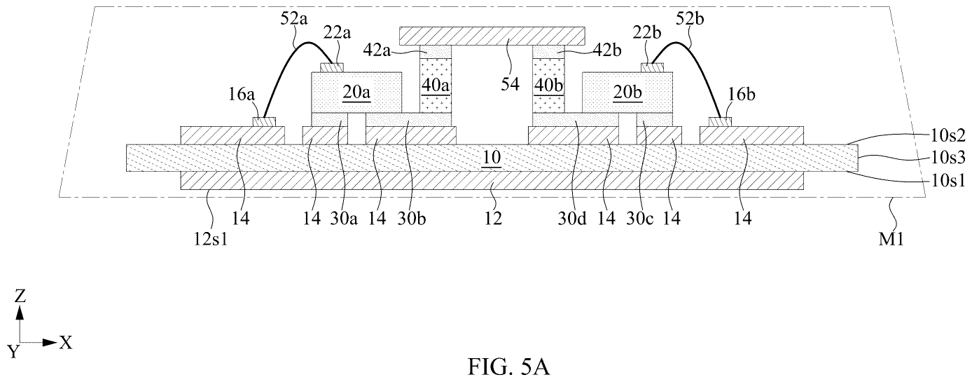

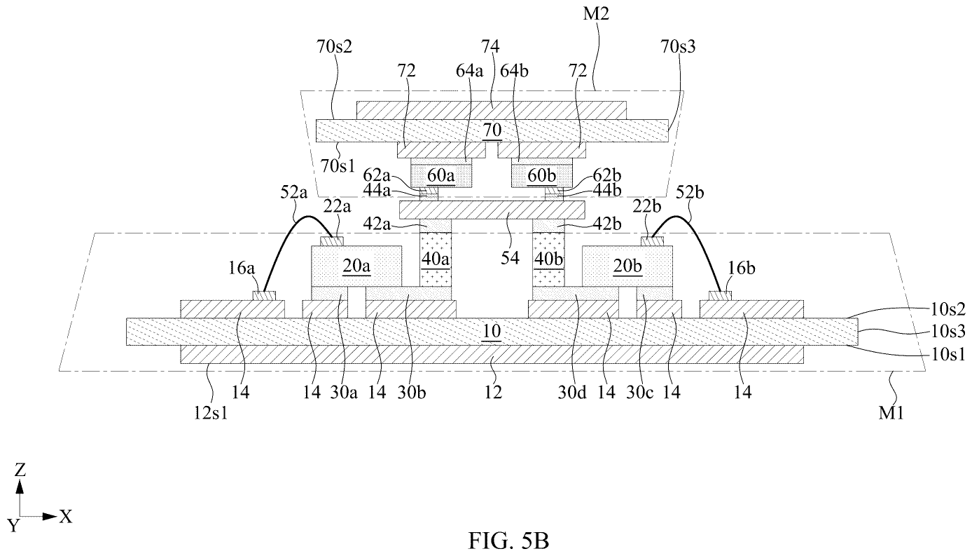

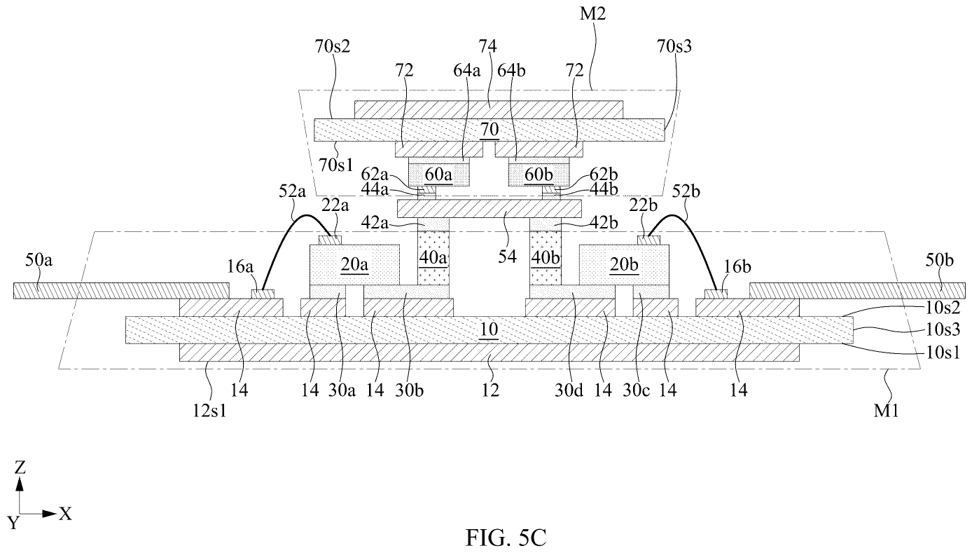

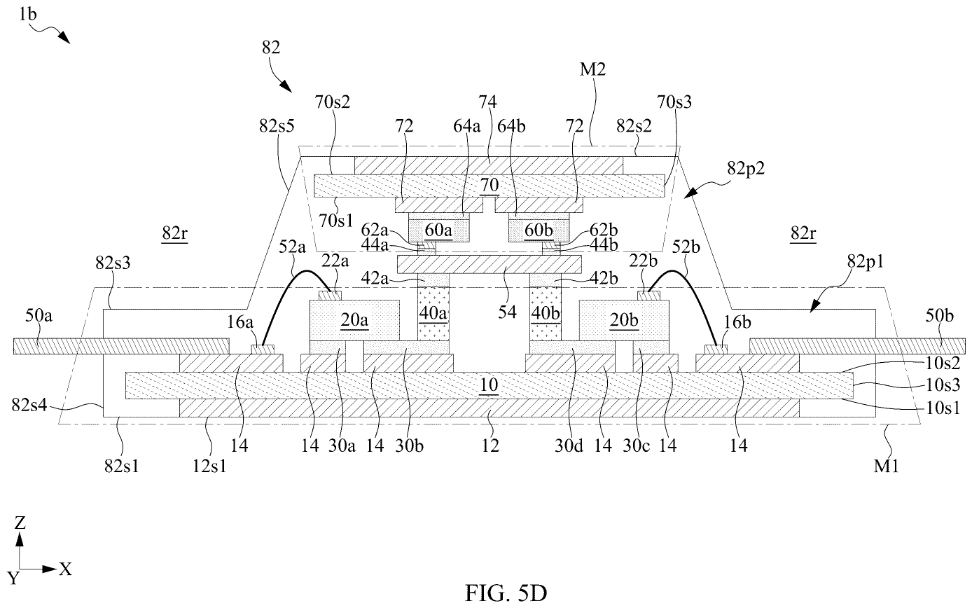

FIG. 5A, FIG. 5B, FIG. 5C, and FIG. 5D illustrate one or more stages of an example of a method for manufacturing an electronic device according to some arrangements of the present disclosure.

Referring to FIG. 5A, the module M1 may be provided. In some arrangements, the module M1 may include the carrier 10, electronic component 20a, electronic component 20b, spacer 40a, spacer 40b, and the conductive feature 54.

Referring to FIG. 5B, the module M2 may be provided. The module M2 may include the electronic component 60a, electronic component 60b, and carrier 70. The module M2 may be stacked over the conductive feature 54 of the module M1.

Referring to FIG. 5C, the terminals 50a and terminals 50b may be formed on or attached to the conductive plate 14 of the carrier 10.

Referring to FIG. 5D, the encapsulant 82 may be formed to encapsulate the module M1 and module M2. In some arrangements, the encapsulant 82 may be formed by a selective molding technique. The recess 82r may be defined by the encapsulant 82. As a result, an electronic device (e.g., the electronic device 1b) may be produced.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first module comprising a first power die with a first dimension;
a second module stacked over the first module and comprising a component with a second dimension different from the first dimension; and
an encapsulant encapsulating the first module and the second module,
wherein the encapsulant defines a recess configured to accommodate an external device.

2. The electronic device of claim 1, wherein the second dimension is less than the first dimension.

3. The electronic device of claim 1, wherein the second module is electrically connected to the first module by a spacer.

4. The electronic device of claim 3, further comprising:
a patterned conductive feature connecting the spacer and the second module.

5. The electronic device of claim 3, wherein a thickness of the spacer is greater than a thickness of the first power die.

6. The electronic device of claim 3, wherein the first module comprises a first carrier supporting the first power die, and in a top view, the first power die is closer to a side of the first carrier than the spacer is.

7. The electronic device of claim 4, wherein the first module further comprises a first carrier and a conductive wire connecting the first carrier and the first power die, and the conductive wire is at an elevation lower than the an elevation of the patterned conductive feature with respect to the first carrier.

8. The electronic device of claim 1, wherein the external device has a profile substantially fitting a profile of the encapsulant.

9. The electronic device of claim 1, wherein the encapsulant has a lateral surface and an upper surface connected to the lateral surface, and wherein the upper surface and the lateral surface define the recess.

10. The electronic device of claim 9, wherein the lateral surface is slanted with respect to the upper surface.

11. The electronic device of claim 1, wherein the first module comprises a second power die, and the component is disposed between the first power die and the second power die in a top view.

12. An electronic device, comprising:
a first carrier;
a first die with a first dimension; and
a second die with a second dimension less than the first dimension, wherein the second die is at an elevation higher than an elevation of the first die with respect to the first carrier, and
wherein the first die is laterally closer to a side of the first carrier than the second die is.

13. The electronic device of claim 12, further comprising:
a second carrier over the second die,
wherein a width of the second carrier is less than that of the first carrier.

14. The electronic device of claim 12, further comprising:
a spacer disposed over the first carrier and electrically connecting the first die and the second die.

15. The electronic device of claim 14, further comprising:
a third die laterally overlapping the first die; and
a fourth die laterally overlapping the second die,
wherein the spacer is electrically connected to the third die and the fourth die, and the spacer is configured to provide a first electrical path, between the first die and the second die, and a second electrical path, between the third die and the fourth die, distinct from the first electrical path.

16. The electronic device of claim 15, wherein the spacer is configured to provide a third electrical path, between the first die and the third die, distinct from the first electrical path and the second electrical path.

17. An electronic device, comprising:
a package structure, comprising:
a carrier; and
a first encapsulant defining a plurality of recesses over the carrier, wherein the plurality of recesses are configured to accommodate additional package structures.

18. The electronic device of claim 17, wherein one of the additional package structures comprises a second encapsulant having a tapered portion encroaching at least one of the plurality of recesses.

19. The electronic device of claim 17, wherein the package structure comprises a first module with a first dimension and a second module with a second dimension less than the first dimension, and one of the additional package structures laterally overlaps the second module.

20. The electronic device of claim 19, wherein the plurality of recesses have different dimensions in a cross-sectional view.
